(19) United States
(12) Patent Application Publication
(10) Pub. No.: US 2025/0259815 A1
(43) Pub. Date: Aug. 14, 2025

(54) THERMOELECTRIC CONTROL FOR A CRUCIBLE FOR USE WITH AN ION SOURCE

(71) Applicant: Applied Materials, Inc., Santa Clara, CA (US)

(72) Inventors: Klaus Becker, Kensington, NH (US); Daniel Alvarado, Methuen, MA (US); Adam M. McLaughlin, Merrimac, MA (US)

(21) Appl. No.: 18/441,483

(22) Filed: Feb. 14, 2024

(51) Int. Cl. H01J 37/08; H01J 37/244; H01J 37/317

(52) U.S. Cl. CPC H01J 37/08; H01J 37/244; H01J 37/3171; H01J 2237/002; H01J 2237/006; H01J 2237/24585

(57) ABSTRACT

A vaporizer that may be used to introduce vapor from a dopant material into the arc chamber is disclosed. The vaporizer includes a crucible and a thermoelectric device disposed on a surface of the crucible near the outlet. The thermoelectric device may be controlled to heat the dopant material to create dopant vapor when desired. Additionally, the thermoelectric device may also be used to quickly cool the surface on which it is disposed. Since the outlet is located near this surface, the outlet also quickly cools, allowing condensation of any dopant vapor in the outlet, thus stopping the flow of vapor into the arc chamber. Additional heaters may be used to further heat the dopant material.

### FIELD

Embodiments of the present disclosure relate to a crucible for use with an ion source and more particularly, a crucible that utilizes temperature control using a thermoelectric device.

### BACKGROUND

Various types of ion sources may be used to create the ions that are used in semiconductor processing equipment. For example, an indirectly heated cathode (IHC) ion source operates by supplying a current to a filament disposed behind a cathode. The filament emits thermionic electrons, which are accelerated toward and heat the cathode, in turn causing the cathode to emit electrons into the arc chamber of the ion source. The cathode is disposed at one end of an arc chamber. A repeller may be disposed on the end of the arc chamber opposite the cathode. The cathode and repeller may be biased so as to repel the electrons, directing them back toward the center of the arc chamber. In some embodiments, a magnetic field is used to further confine the electrons within the arc chamber. A plurality of sides is used to connect the two ends of the arc chamber.

An extraction aperture is disposed along one of these sides, proximate the center of the arc chamber, through which the ions created in the arc chamber may be extracted.

In certain embodiments, it may be desirable to create ions of a particular species, which at room temperature does not have any gaseous compounds that are suitable for use in an ion source. Examples of such species are aluminum and indium. In these cases a vaporizer is installed in close proximity to the arc chamber and the hot vapor from a solid charge in the vaporizer is introduced into the arc chamber as a gas. For the two examples given above this solid material could be aluminum-trichloride or indium-triiodide. However, these vaporizers have slow transition times (i.e., warm up and cool down times), making it difficult to switch modes of operations quickly.

Therefore, it would be beneficial if there were a vaporizer that did not suffer from these drawbacks.

### SUMMARY

A vaporizer that may be used to introduce vapor from a dopant material into the arc chamber is disclosed. The vaporizer includes a crucible and a thermoelectric device disposed on a surface of the crucible near the outlet. The thermoelectric device may be controlled to heat the dopant material to create dopant vapor when desired. Additionally, the thermoelectric device may also be used to quickly cool the surface on which it is disposed. Since the outlet is located near this surface, the outlet also quickly cools, allowing condensation of any dopant vapor in the outlet, thus stopping the flow of vapor into the arc chamber. Additional heaters may be used to further heat the dopant material.

According to one embodiment, a vaporizer is disclosed. The vaporizer comprises a crucible having a plurality of walls that define a crucible chamber; and a thermoelectric device disposed against at least one wall of the crucible. In some embodiments, the vaporizer includes an isothermal block, wherein the thermoelectric device is disposed between the isothermal block and the at least one wall. In certain embodiments, the isothermal block is maintained at a near constant temperature. In some embodiments, the thermoelectric device is configured to heat the at least one wall in a first mode and cool the at least one wall in a second mode. In certain embodiments, an outlet from the crucible chamber is disposed near the at least one wall, such that in the second mode, cooling of the at least one wall allows vapor from a dopant material disposed within the crucible chamber to condense in the outlet, so as to inhibit flow of vapor from the crucible chamber to an ion source. In some embodiments, the vaporizer includes a thermal controller in communication with the thermoelectric device, the thermal controller comprising a bipolar voltage output to allow operation in the first mode and the second mode. In certain embodiments, a direction of DC current from the bipolar voltage output determines a mode of operation and an amplitude of the DC current determines an amount of heating or cooling provided by the thermoelectric device. In some embodiments, the vaporizer includes a temperature sensor disposed against one wall of the crucible chamber, wherein the thermal controller uses information from the temperature sensor to control the bipolar voltage output. In some embodiments, the vaporizer includes a thermal controller in communication with the thermoelectric device, the thermal controller comprising a unipolar voltage output to allow operation in the first mode; and a second voltage source to allow operation in the second mode. In some embodiments, a secondary heater is used to supplement heat provided by the thermoelectric device in the first mode. In certain embodiments, the secondary heater comprises a second thermoelectric device, a resistive heater or heat pipes.

According to another embodiment, an ion implantation system is disclosed. The ion implantation system comprises an ion source to generate an ion beam; one or more beamline components located downstream from the ion source to direct the ion beam toward a workpiece holder; and a vaporizer in communication with the ion source to supply a dopant vapor to the ion source; wherein the vaporizer comprises a crucible chamber to hold a dopant material and a thermoelectric device disposed against at least one wall of the crucible chamber. In some embodiments, the vaporizer comprises an isothermal block, wherein the thermoelectric device is disposed between the isothermal block and the at least one wall. In certain embodiments, the isothermal block is maintained at a near constant temperature. In some embodiments, the vaporizer is adapted to operate in two modes, wherein, in a first mode, at least a portion of the crucible chamber is heated by the thermoelectric device and wherein, in a second mode, at least a portion of the crucible chamber is actively cooled by the thermoelectric device to cause condensation of the dopant vapor. In some embodiments, the vaporizer comprises a thermal controller in communication with the thermoelectric device, the thermal controller comprising a bipolar voltage output to allow operation in the first mode and the second mode. In certain embodiments, a direction of DC current from the bipolar voltage output determines a mode of operation and an amplitude of the DC current determines an amount of heating or cooling provided by the thermoelectric device. In some embodiments, the vaporizer comprises a thermal controller in communication with the thermoelectric device, the thermal controller comprising a unipolar voltage output to allow operation in the first mode; and a second voltage source to allow operation in the second mode. In some embodiments, the vaporizer comprises a secondary heater to supplement heat provided to the crucible chamber by the thermoelectric device in the first mode. In certain embodiments, the secondary heater comprises a second thermoelectric device, a resistive heater or heat pipes.

### BRIEF DESCRIPTION OF THE FIGURES

For a better understanding of the present disclosure, reference is made to the accompanying drawings, which are incorporated herein by reference and in which:

FIG. 1 is an indirectly heated cathode (IHC) ion source for introducing vapor in accordance with one embodiment;

FIG. 2 is a diagram showing a cross section of the vaporizer of FIG. 1; and

FIG. 3 is an ion implantation system that utilizes the ion source and crucible described herein.

### DETAILED DESCRIPTION

As noted above, certain dopants, such as aluminum and other metals, are typically provided into an arc chamber using a vaporizer. The present disclosure describes a crucible that overcomes the shortcomings of the prior art.

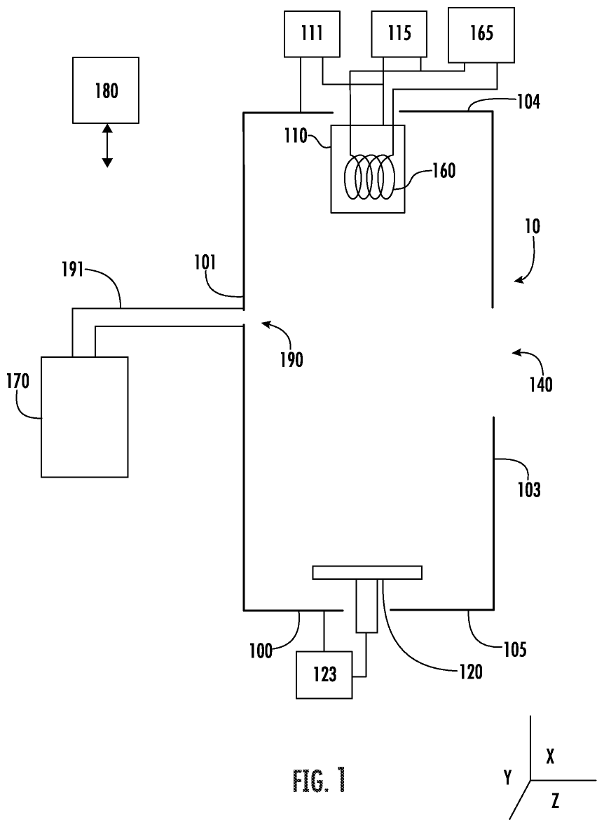

FIG. 1 shows an IHC ion source 10 in communication with the vaporizer 170. The IHC ion source 10 includes an arc chamber 100, comprising two opposite ends, and walls 101 connecting to these ends. The walls 101 of the arc chamber 100 may be constructed of an electrically conductive material and may be in electrical communication with one another. In some embodiments, a liner may be disposed proximate one or more of the walls 101. A cathode 110 is disposed in the arc chamber 100 at a first end 104 of the arc chamber 100. A filament 160 is disposed behind the cathode 110. The filament 160 is in communication with a filament power supply 165. The filament power supply 165 is configured to pass a current through the filament 160, such that the filament 160 emits thermionic electrons. Cathode bias power supply 115 biases filament 160 negatively relative to the cathode 110, so these thermionic electrons are accelerated from the filament 160 toward the cathode 110 and heat the cathode 110 when they strike the back surface of cathode 110. The cathode bias power supply 115 may bias the filament 160 so that it has a voltage that is between, for example, 200V to 1500V more negative than the voltage of the cathode 110. The cathode 110 then emits thermionic electrons on its front surface into arc chamber 100.

Thus, the filament power supply 165 supplies a current to the filament 160. The cathode bias power supply 115 biases the filament 160 so that it is more negative than the cathode 110, so that electrons are attracted toward the cathode 110 from the filament 160. In certain embodiments, the cathode 110 may be biased relative to the arc chamber 100, such as by arc power supply 111. In other embodiments, the cathode 110 may be electrically connected to the arc chamber 100, so as to be at the same voltage as the walls 101 of the arc chamber 100. In these embodiments, arc power supply 111 may not be employed and the cathode 110 may be electrically connected to the walls 101 of the arc chamber 100. In certain embodiments, the arc chamber 100 is connected to electrical ground.

On the second end 105, which is opposite the first end 104, a repeller 120 may be disposed. The repeller 120 may be biased relative to the arc chamber 100 by means of a repeller bias power supply 123. In other embodiments, the repeller 120 may be electrically connected to the arc chamber 100, so as to be at the same voltage as the walls 101 of the arc chamber 100. In these embodiments, repeller bias power supply 123 may not be employed and the repeller 120 may be electrically connected to the walls 101 of the arc chamber 100. In still other embodiments, a repeller 120 is not employed.

The cathode 110 and the repeller 120 are each made of an electrically conductive material, such as a metal or graphite.

In certain embodiments, a magnetic field is generated in the arc chamber 100. This magnetic field is intended to confine the electrons along one direction. The magnetic field typically runs parallel to the walls 101 from the first end 104 to the second end 105. For example, electrons may be confined in a column that is parallel to the direction from the cathode 110 to the repeller 120. Thus, electrons do not experience any electromagnetic force to move in this direction. However, movement of the electrons in other directions may experience an electromagnetic force.

Disposed on one side of the arc chamber 100, referred to as the extraction plate 103, may be an extraction aperture 140. In FIG. 1, the extraction aperture 140 is disposed on a side that is perpendicular to the page. A gas inlet 190 may be disposed on one wall of the arc chamber 100.

Further, the IHC ion source 10 may be in communication with the vaporizer 170. The vaporizer 170 is used to vaporize a solid dopant material, such that the dopant vapor travels from the vaporizer 170 through vapor channel 191 and enters the arc chamber 100 via gas inlet 190.

A controller 180 may be in communication with one or more of the power supplies such that the voltage or current supplied by these power supplies may be modified. The controller 180 may also be in communication with the thermal controller, coolers and heaters as described below. The controller 180 may include a processing unit, such as a microcontroller, a personal computer, a special purpose controller, or another suitable processing unit. The controller 180 may also include a non-transitory storage element, such as a semiconductor memory, a magnetic memory, or another suitable memory. This non-transitory storage element may contain instructions and other data that allows the controller 180 to perform the functions described herein.

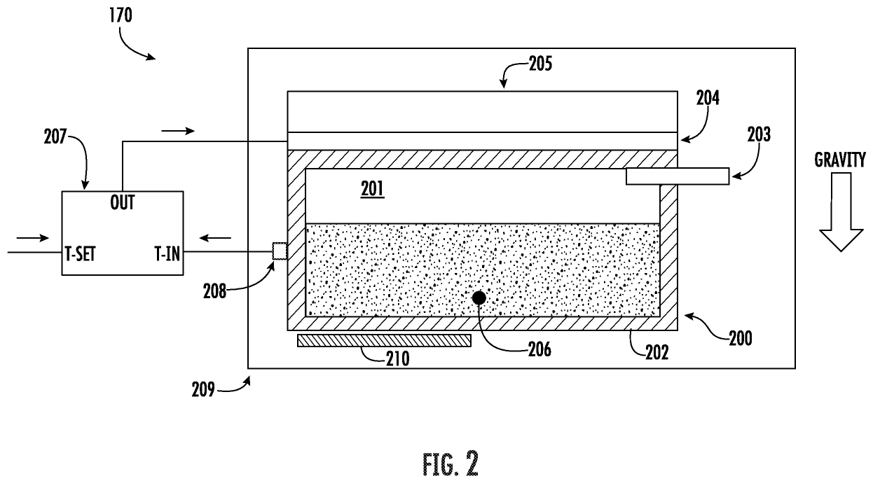

FIG. 2 shows the vaporizer 170 in more detail. The vaporizer 170 includes a crucible 200 comprising a plurality of walls 202 that define a crucible chamber 201. In some embodiments, the walls 202 may be made from a refractory metal, or may be constructed from graphite. The walls 202 may define a rectangular prism, a cylinder or another suitable shape. An outlet 203 may be disposed in one of these walls 202, and may be positioned to be near the top of the crucible 200 such that vapor passes through the outlet 203. In some embodiments, the outlet 203 may have a round cross-section. In certain embodiments, the round cross-section may have a diameter between 1/16″ and 14″. In other embodiments, a different shaped outlet may be used, such as one having a larger surface area to cross-sectional area ratio than a circle to facilitate faster condensation. Specifically, gravity draws the dopant material 206 within the crucible chamber 201 to the bottom of the crucible 200. The top of the crucible 200 is defined as the portion of the crucible 200 furthest from the bottom.

A thermoelectric device 204 is sandwiched between one or more walls 202 of the crucible 200 and an isothermal block 205. Specifically, the thermoelectric device 204 is pressed against the exterior surface of one or more walls 202 that are near the outlet 203. These walls may include the wall in which the outlet 203 is disposed, or walls adjacent to that wall. These one or more walls may be referred to as temperature controlled walls. For example, in FIG. 2, the crucible 200 is shaped as a rectangular prism, where the outlet 203 is located near the top of one of the side walls. The thermoelectric device 204 is disposed against the top wall, which is near the outlet 203 and adjacent to the wall containing the outlet 203. Note that if the crucible was tilted, the thermoelectric device 204 may still be disposed along the wall 202 that is adjacent to or near the outlet 203.

The isothermal block 205 may be a block of material that maintains a near constant temperature. This may be achieved by utilizing a sufficiently large block such that the heat transferred to and from the thermoelectric device 204 have little effect on the overall temperature of the isothermal block 205. In another embodiment, the isothermal block 205 may have one or more fluid channels therethrough that allow the flow of a fluid that circulates through the fluid channels to maintain the isothermal block 205 at a constant or near constant temperature. In certain embodiments, the term “near constant” refers to a temperature that does not vary by more than +20° C. In some embodiments, the isothermal block 205 is maintained at or near 25° C.

The thermoelectric device 204 utilizes the Peltier effect to convert DC current into heat transfer. Specifically, in FIG. 2, one side of the thermoelectric device 204 is maintained at constant or near constant temperature due to its contact with the isothermal block 205. If the DC current through the thermoelectric device 204 flows in a first direction, heat is transferred from the side adjacent to the isothermal block 205 to the side adjacent to the wall 202 of the crucible 200. This first mode serves to heat the wall 202. If, conversely, the DC current through the thermoelectric device 204 flows in a second direction, heat is transferred from the side adjacent to the wall 202 of the crucible 200 to the side adjacent to the isothermal block 205. This second mode serves to cool the wall 202. Thus, the direction of DC current flow determines the direction of heat transfer while the magnitude of the DC current determines the amount of heat transfer. In other words, the direction of DC current flow determines the mode of operation and the magnitude of the DC current determines the amount of heating or cooling provided by the thermoelectric device 204.

In one embodiment, the thermoelectric device 204 is in communication with a thermal controller 207 that may include a bipolar voltage output. The thermal controller 207 receives an input from a temperature sensor 208. The temperature sensor 208 may be a thermocouple or another type of sensor. The temperature sensor 208 may be disposed along one of the walls 202 of the crucible 200. In one embodiment, the temperature sensor 208 may be disposed against a wall 202 that is contacted by the dopant material 206, such as the bottom wall or the lower portion of a side wall. In operation, the thermal controller 207 receives a set temperature (labelled T-SET) as an input, and also receives the information from the temperature sensor 208. The set temperature may be provided by another controller, such as controller 180. Based on the difference between these two temperatures, the thermal controller 207 determines the direction of DC current flow through the thermoelectric device 204. For example, if the set temperature is greater than the temperature indicated by the temperature sensor 208, the thermal controller 207 will flow DC current through the thermoelectric device 204 in the first direction to add heat to the crucible 200. If the set temperature is less than the temperature indicated by the temperature sensor 208, the thermal controller 207 will flow DC current through the thermoelectric device 204 in the second direction to remove heat from the crucible 200. Thus, the thermal controller 207 is able to heat or cool the crucible 200, using the isothermal block 205 as a heat sink or heat source, depending on the direction of heat transfer. In certain embodiments, the thermal controller 207 may receive temperature information from one or more additional temperature sensors. For example, in some embodiments, a temperature sensor may be disposed on or near the thermoelectric device 204. In this way, the thermal controller 207 may control the DC current such that the temperature of the thermoelectric device 204 never exceeds a predetermined temperature threshold.

The vaporizer 170, which includes the crucible 200, the thermoelectric device 204, the temperature sensor 208 and the isothermal block 205, are disposed within a vacuum chamber 209, with the IHC ion source 10 and are thermally insulated from all other components within the vacuum chamber 209 as much as is practical. Connections for power, signals, and facilities pass through the wall of vacuum chamber 209 into atmosphere. The thermal controller 207 may be disposed in atmospheric conditions.

In operation, a dopant material 206 is placed in the crucible chamber 201. The dopant material 206 is in solid form, and may be aluminum or a different metal. Gravity will force the dopant material 206 to the bottom of the crucible chamber 201. The controller 180 may instruct the thermal controller 207 to generate dopant vapor. In response, the set temperature for the thermal controller 207 is set to a first temperature, which is an elevated temperature. This elevated temperature may be up to 300° C. or more in some embodiments. The first temperature may be high enough to vaporize the dopant material 206. The dopant vapor then flows through outlet 203 and vapor channel 191 to the arc chamber 100. At a later time, it may be desirable to stop the flow of dopant vapor to the ion source. The controller 180 may instruct the thermal controller 207 to stop the flow of dopant vapor. In response, the set temperature is set to a second temperature, which is lower than the first temperature. This second temperature may be sufficiently low such that dopant vapor condenses on the temperature controlled wall. In some embodiments, this second temperature may be less than 30° C. In some embodiments, the second temperature may be between 15° C. and 30° C. This second temperature may be based on the vapor pressure of the dopant material 206. Further, since the outlet 203 is near the temperature controlled wall, dopant vapor condenses within the outlet, effectively blocking the passage of any dopant vapor still in the crucible chamber 201 from exiting. Thus, as the dopant material 206 cools, it condenses on the temperature controlled wall and within the outlet 203. The next time that dopant vapor is requested, the set temperature is changed to the first temperature. This first temperature is sufficient to vaporize any condensed dopant in the outlet 203 and on the temperature controlled wall, allowing the flow of dopant vapor to the arc chamber 100.

Thus, the thermoelectric device 204 provides several functions. First, when set to the second temperature, the temperature controlled wall causes the condensation of dopant vapor on the wall as well as within the outlet 203. This prevents the flow of dopant vapor to the ion source. Second, when set to the first temperature, the temperature controlled wall causes the vaporization of dopant material that may have condensed within the outlet 203. Third, in some embodiments, the temperature controlled wall also causes the vaporization of the dopant material 206.

Thus, the thermoelectric device 204 allows at least two modes of operation for the vaporizer 170. There is a first mode of operation where the thermoelectric device 204 acts as a heater, which allows the flow of dopant vapor through the outlet 203. Thus, in the first mode, at least a portion of the crucible chamber 201 is heated. There is also a second mode of operation, wherein the thermoelectric device 204 acts as a cooler, forcing dopant vapor to condense on the temperature controlled wall and in the outlet 203, effectively blocking the passage of any dopant vapor to the arc chamber 100. Thus, in the second mode, at least a portion of the crucible chamber 201 is actively cooled.

Further, while FIG. 2 shows one embodiment, several variations are also possible.

In certain embodiments, the heat provided by the thermoelectric device 204 may be supplemented when operating in the first mode. For example, a secondary heater 210 may be used to heat the surface against which the dopant material 206 is disposed. This secondary heater 210 may be a second thermoelectric device, and may be operated in the same manner as the thermoelectric device 204. In a variation of this embodiment, the second thermoelectric device may only be used as a heater. In another embodiment, the secondary heater 210 may be a resistive heater. In this embodiment, the resistive heater may be actuated whenever the thermoelectric device 204 is being used as a heater. In another embodiment, the secondary heater 210 may be heat pipes that are embedded in one or more walls 202 of the crucible 200 which are actuated when the thermoelectric device 204 acts as a heater.

Note that FIG. 2 shows the thermoelectric device 204 placed against a wall different from the walls against which the dopant material is disposed. However, in another embodiment, the thermoelectric device 204 may be placed against a wall that is only in partial contact with the dopant material 206. For example, the thermoelectric device 204 may be disposed along the right side wall in FIG. 2. This placement still allows the thermoelectric device 204 to control the temperature within the outlet 203. Thus, the thermoelectric device 204 may be disposed along the wall that includes the outlet 203, along a wall adjacent to the wall that includes the outlet 203, or along a different wall that is near the outlet 203.

In another embodiment, the thermal controller 207 may utilize a unipolar voltage output. In this embodiment, the thermal controller 207 may be used when heating is requested and a second voltage source may be used in the second mode. In one embodiment, a second thermal controller may be used when cooling is requested. The selection of which of the outputs from these two thermal controllers is provided to the thermoelectric device 204 may be achieved using an analog switch or a relay. In another embodiment, the second voltage source may be a fixed voltage that may be used for cooling. Again, the appropriate signal may be selected using an analog switch or a relay.

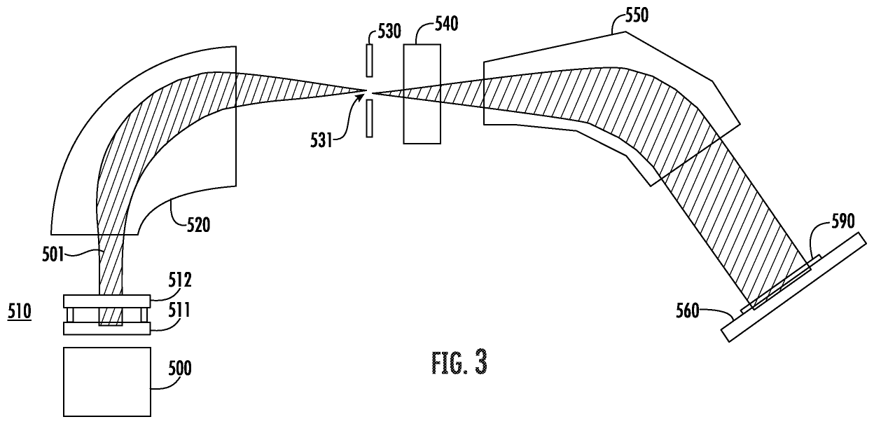

FIG. 3 shows an ion implanter that may utilize the ion source described herein. The ion implanter includes an ion source 500, which may be any of the ion sources described above. As noted above, in certain embodiments, the ion source 500 may be an IHC ion source. In another embodiment, the ion source 500 may be an RF ion source. In this embodiment, an RF antenna may be disposed against a dielectric window. This dielectric window may comprise part or all of one of the chamber walls. The RF antenna may comprise an electrically conductive material, such as copper. An RF power supply is in electrical communication with the RF antenna. The RF power supply may supply an RF voltage to the RF antenna. The power supplied by the RF power supply may be between 0.1 and 10 kW and may be any suitable frequency, such as between 1 and 100 MHZ. Further, the power supplied by the RF power supply may be pulsed. Other embodiments are also possible. For example, the plasma may be generated in a different manner, such as by a Bernas ion source, a capacitively coupled plasma (CCP) source, microwave or ECR (electron-cyclotron-resonance) ion source. The manner in which the plasma is generated is not limited by this disclosure.

One chamber wall, referred to as the extraction plate, includes an extraction aperture. The extraction aperture may be an opening through which the ions 501 generated in the ion source chamber are extracted and directed toward a workpiece 590. The extraction aperture may be any suitable shape. In certain embodiments, the extraction aperture may be oval or rectangular shaped.

Disposed outside and proximate the extraction aperture of the ion source 500 are extraction optics 510. In certain embodiments, the extraction optics 510 comprise one or more electrodes. In certain embodiments, the extraction optics 510 comprises a suppression electrode 511, which is negatively biased relative to the plasma so as to attract ions through the extraction aperture. The suppression electrode 511 may be electrically biased using a suppression power supply. The suppression electrode 511 may be biased so as to be more negative than the extraction plate of the ion source 500.

In some embodiments, the extraction optics 510 includes a second electrode 512. The second electrode 512 may be disposed proximate the suppression electrode 511. The second electrode 512 may be electrically connected to a second electrode power supply. In other embodiments, the second electrode 512 may be electrically grounded so that the second electrode power supply is not used.

In other embodiments, the extraction optics 510 may comprise in excess of two electrodes, such as three electrodes or four electrodes. In these embodiments, the electrodes may be functionally and structurally similar to those described above, but may be biased at different voltages.

Located downstream from the extraction optics 510 is a mass analyzer 520. The mass analyzer 520 uses magnetic fields to guide the path of the extracted ions 501. The magnetic fields affect the flight path of ions according to their mass and charge. A mass resolving device 530 that has a resolving aperture 531 is disposed at the output, or distal end, of the mass analyzer 520. By proper selection of the magnetic fields, only those ions 501 that have a selected mass and charge will be directed through the resolving aperture 531. Other ions will strike the mass resolving device 530 or a wall of the mass analyzer 520 and will not travel any further in the system.

One or more beamline components may be disposed downstream from the mass resolving device 530. For example, a collimator 540 may be disposed downstream from the mass resolving device 530. The collimator 540 accepts the extracted ions 501 that pass through the resolving aperture 531 and creates a ribbon ion beam formed of a plurality of parallel or nearly parallel beamlets. In other embodiments, the ion beam may be a spot beam. In this embodiment, an electrostatic scanner is used to move the spot beam in a first direction, as defined below.

Located downstream from the collimator 540 may be an acceleration/deceleration stage 550. The acceleration/deceleration stage 550 may be an electrostatic filter. The electrostatic filter is a beam-line lens component configured to independently control deflection, deceleration, and focus of the ion beam. The output from the acceleration/deceleration stage 550 may be a ribbon ion beam having a width in the first direction, which is much greater than its height in the second direction. Located downstream from the acceleration/deceleration stage 550 is the workpiece holder 560.

The workpiece 590, which may be, for example, a silicon wafer, a silicon carbide wafer, or a gallium nitride wafer, is disposed on the workpiece holder 560. The workpiece holder 560 may be moved in the second direction, which is perpendicular to the first direction, to allow the entirety of the workpiece 590 to be processed by the ion beam.

The embodiments described above in the present application may have many advantages. First, by using a thermoelectric device 204, it is possible to both heat the crucible as well as cool it. The ability to cool the outlet 203 allows it to become blocked, stopping the passage of vapor to the arc chamber 100. Thus, this crucible, unlike traditional vaporizers, provides fast turn off times. Additionally, the thermoelectric device 204 may be one or more thin sheets of material, having a thickness of between 3 to 5 mm in some embodiments. This allows the heating of the crucible to be performed in a very small volume, allowing a large crucible chamber to be used in the same space currently utilized by conventional vaporizers.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

What is claimed is:

1. A vaporizer, comprising:
a crucible having a plurality of walls that define a crucible chamber; and
a thermoelectric device disposed against at least one wall of the crucible.

2. The vaporizer of claim 1, further comprising an isothermal block, wherein the thermoelectric device is disposed between the isothermal block and the at least one wall.

3. The vaporizer of claim 2, wherein the isothermal block is maintained at a near constant temperature.

4. The vaporizer of claim 1, wherein the thermoelectric device is configured to heat the at least one wall in a first mode and cool the at least one wall in a second mode.

5. The vaporizer of claim 4, wherein an outlet from the crucible chamber is disposed near the at least one wall, such that in the second mode, cooling of the at least one wall allows vapor from a dopant material disposed within the crucible chamber to condense in the outlet, so as to inhibit flow of vapor from the crucible chamber to an ion source.

6. The vaporizer of claim 4, further comprising a thermal controller in communication with the thermoelectric device, the thermal controller comprising a bipolar voltage output to allow operation in the first mode and the second mode.

7. The vaporizer of claim 6, wherein a direction of DC current from the bipolar voltage output determines a mode of operation and an amplitude of the DC current determines an amount of heating or cooling provided by the thermoelectric device.

8. The vaporizer of claim 6, further comprising a temperature sensor disposed against one wall of the crucible chamber, wherein the thermal controller uses information from the temperature sensor to control the bipolar voltage output.

9. The vaporizer of claim 4, further comprising a thermal controller in communication with the thermoelectric device, the thermal controller comprising a unipolar voltage output to allow operation in the first mode; and a second voltage source to allow operation in the second mode.

10. The vaporizer of claim 4, further comprising a secondary heater to supplement heat provided by the thermoelectric device in the first mode.

11. The vaporizer of claim 10, wherein the secondary heater comprises a second thermoelectric device, a resistive heater or heat pipes.

12. An ion implantation system, comprising:
an ion source to generate an ion beam;
one or more beamline components located downstream from the ion source to direct the ion beam toward a workpiece holder; and
a vaporizer in communication with the ion source to supply a dopant vapor to the ion source;
wherein the vaporizer comprises a crucible chamber to hold a dopant material and a thermoelectric device disposed against at least one wall of the crucible chamber.

13. The ion implantation system of claim 12, wherein the vaporizer comprises an isothermal block, wherein the thermoelectric device is disposed between the isothermal block and the at least one wall.

14. The ion implantation system of claim 13, wherein the isothermal block is maintained at a near constant temperature.

15. The ion implantation system of claim 12, wherein the vaporizer is adapted to operate in two modes, wherein, in a first mode, at least a portion of the crucible chamber is heated by the thermoelectric device and wherein, in a second mode, at least a portion of the crucible chamber is actively cooled by the thermoelectric device to cause condensation of the dopant vapor.

16. The ion implantation system of claim 15, wherein the vaporizer comprises a thermal controller in communication with the thermoelectric device, the thermal controller comprising a bipolar voltage output to allow operation in the first mode and the second mode.

17. The ion implantation system of claim 16, wherein a direction of DC current from the bipolar voltage output determines a mode of operation and an amplitude of the DC current determines an amount of heating or cooling provided by the thermoelectric device.

18. The ion implantation system of claim 15, wherein the vaporizer comprises a thermal controller in communication with the thermoelectric device, the thermal controller comprising a unipolar voltage output to allow operation in the first mode; and a second voltage source to allow operation in the second mode.

19. The ion implantation system of claim 15, wherein the vaporizer comprises a secondary heater to supplement heat provided to the crucible chamber by the thermoelectric device in the first mode.

20. The ion implantation system of claim 19, wherein the secondary heater comprises a second thermoelectric device, a resistive heater or heat pipes.
